(19) United States
(12) Patent Application Publication
(10) Pub. No.: US 2011/0133725 A1
(43) Pub. Date: Jun. 9, 2011

(54) HALL-TYPE LINEAR-TRAVEL SENSOR FOR INTERMEDIATE TRAVEL

(76) Inventor: Werner DENGLER, Gerertsberg (AT)

(21) Appl. No.: 12/959,427

(22) Filed: Dec. 3, 2010

(30) Foreign Application Priority Data
Dec. 4, 2009 (DE) 102009056734.8

(51) Int. Cl. G01B 7/14; G01R 33/07

(52) U.S. Cl. 324/207.2

(57) ABSTRACT

A sensor assembly for detecting the position of a linearly movable element has a magnet and a sensor for detecting the position of the magnet. A stationary support is provided that is configured for carrying the sensor and for guiding the element that carries the magnet and is linearly movable relative to the support.

### FIELD OF THE INVENTION

The invention relates to a sensor assembly configured for detecting the position of a linearly movable element and comprising a magnet and a sensor detecting the position of the magnet.

### BACKGROUND OF THE INVENTION

According to the prior art, measurement systems for straight-line displacement and based on the Hall effect are usually used for measurements up to about 40 mm. Measurements of longer displacements are based on complicated sine-cosine magnetizations or are implemented by inductive, capacitive or resistive systems.

### OBJECT OF THE INVENTION

The object of the invention is to provide a sensor assembly that measures linear displacement in a wear-free and simple manner and with good accuracy. In particular the manufacture of the magnetic target (magnet) is to be kept as simple as possible so to as reduce in particular costs when using such a sensor assembly in the vehicle-related (automotive) field.

### SUMMARY OF THE INVENTION

According to the invention, a stationary support is provided that carries the sensor and that guides the element having the magnet and linearly movable relative to the support. The necessary parts can be manufactured in a simple manner, for example in a plastic injection-molding process and can be assembled to form the finished sensor assembly. The stationary support carries the magnet so that the linearly movable element can be moved back and forth relative to the stationary support and itself carries the magnet such that during the back and forth movement of the linearly movable element, there is a change in field lines change that can be detected by the sensor, in particular by a magnetically sensitive sensor.

For the purpose of a simple implementation of the magnet, in one development of the invention, the magnet is elongated, has an angular cross-section, and is diagonally magnetized along its longitudinal extension. This means that in this first approach to a solution, a diagonally magnetized magnet material is used in a one-piece magnet. The manufacture of such a magnet is quite simple because it is formed as a plastic-bonded magnet and is in particular formed in an advantageous manner from an anisotropic magnet material, the plastic-bonded magnet, in particular with anisotropic magnet material (or other conceivable suitable magnet material), being magnetized directly during injection molding with permanent magnets mounted in the mold. With respect to the manufacturing process that is important here, this means for the magnet that the magnet is manufactured in an extrusion process or injection-molding process in which a negative mold that defines the subsequent shape of the magnet is filled with a suitable magnetizable plastic material (that is not yet or only slightly magnetized), the magnetizable material being diagonally magnetized with a permanent magnet that is set in the mold (injection mold). This way, the magnet can be manufactured in a fast and simple manner and, due to its elongated shape, the magnet is very well suited so that long travels, for example with a length up to 400 mm (or smaller or greater) can be detected therewith.

In an alternative configuration according to the invention the magnet has an elongated shape and a round or oval cross-section and is helically magnetized along its longitudinal extension. With this second important embodiment a helically magnetized magnet is therefore provide by an adequate manufacturing method. It can be extruded in a simple manner as a plastic-bonded magnet and can be magnetized by a rotating magnetizing device. This means that the helically magnetized magnet is manufactured by an extrusion method and from a plastic-bonded magnet material that is in particular formed from an anisotropic magnetic material. During manufacturing or afterward, the plastic-bonded magnet material, in particular the anisotropic magnet material, is is magnetized by a rotating magnetizing device that, at the same time, moves along the axial extension so that after this manufacture, the magnet is helically magnetized along its longitudinal extension. Preferably, from the beginning to the end of the one-piece magnet, a single change of polarity is provided, it also being conceivable that the polarity change along the longitudinal extension of the magnet changes more than once, thus several times.

With respect to the functionality of the sensor assembly according to the invention, the same measuring principle applies for the diagonally and longitudinally extending magnet as well as the helically magnetized magnet. On an imaginary center line, a magnetically sensitive sensor, in particular a Hall-effect sensor, is mounted and positioned in or on the support of the sensor assembly, the sensor being able to detect the gradients of the magnetic field lines that change during straight-line movement of the magnet relative to the sensor. When the magnet moves in a straight line relative to the sensor then, from the sensor's point of view, the angles of the magnetic field lines are continuously changed so that the change can be detected and evaluated.

### BRIEF DESCRIPTION OF THE DRAWING

An embodiment of a sensor assembly according to the invention as well as the two variants of the position-indicating magnet are shown in the figures and explained in more detail hereinafter. In the drawing:

FIG. 1 is a schematic view of the assembly of this invention in two different positions;

FIG. 2 is a perspective views of two magnets according to the invention; and

FIG. 3 is a perspective view of a magnet according to the invention.

### SPECIFIC DESCRIPTION

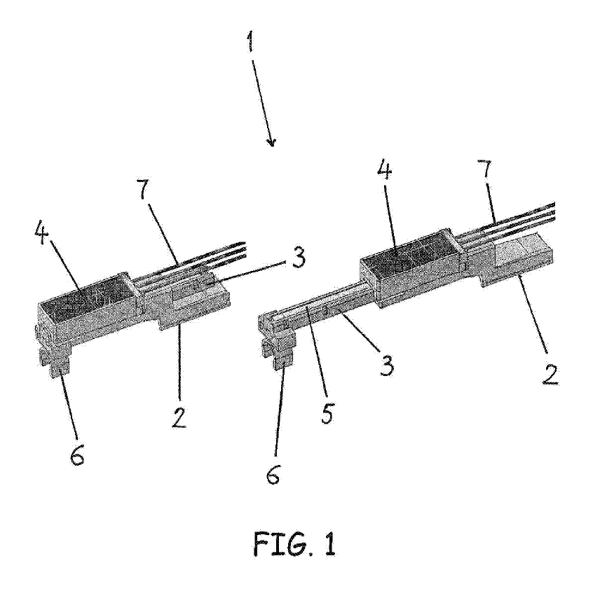

FIG. 1 schematically shows details of a sensor assembly designated with reference 1 and comprising a stationary support 2. The support 2 is mounted and secured in a suitable manner in the provided installation location and carries an element 3, preferably configured as a slide movable in a straight line relative to the stationary support 2. The shapes of the linearly movable element 3 and its guide in the stationary support 2 are complementary to each other so that the element 3 can be moved linearly relative to the support 2. The stationary support 2 further has a sensor 4, in particular a magnetically sensitive sensor such as for example a Hall-effect sensor. A magnet 5, in particular a permanent magnet, is mounted in or on the linearly movable element 3. Furthermore, the element 3 has a mount 6 by means of which it can be attached to a structure whose position changes relative to the stationary support 2 and is to be measured by the sensor 4. In one configuration of the invention, the stationary support 2 and/or the linearly movable element 3 can be components manufactured separately from each other in a plastic injection-molding process. Alternatively to this it is conceivable that the linearly movable element 3 does not have a mount 6, but the element 3 is and integral part of the structure whose is to be detected. A signal line 7 (or a plurality of signal lines) runs as necessary from the sensor 4 to a downstream evaluation device.

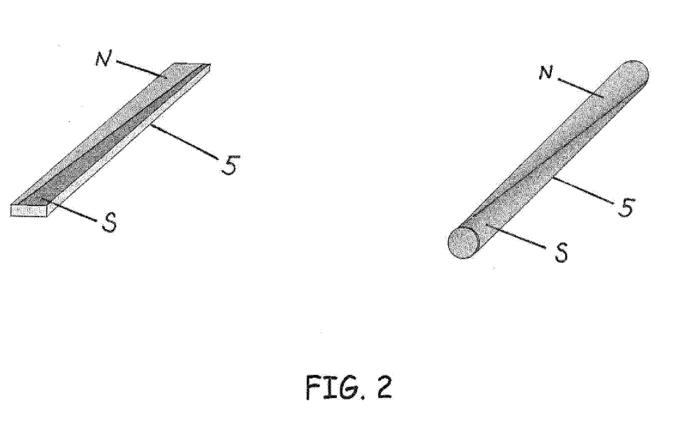

FIG. 2 shows two types of the magnet 5. The left illustration in FIG. 2 shows that the magnet 5 is elongated, with a length that preferably corresponds to the length of the displacement to be detected. To simplify the fixation and mounting of the magnet 5 on the linearly movable element 3, the magnet 5 has an angular, in particular rectangular or square cross-section, and is diagonally magnetized along its longitudinal extension. The diagonal magnetization is illustrated by the north pole N and the south pole S.

The right illustration in FIG. 2 shows that here too, the magnet 5 is elongated, but has a round or oval cross-section that is suitable if the holder for the magnet 5 in the element 3 has a corresponding cross-section or the structural conditions or movement conditions of the sensor assembly 1 require such a cross-section. It is also shown that here, the magnet 5 is helically magnetized once along its longitudinal length. In the embodiment according to FIG. 2, right illustration, the change from north pole N to south pole S over its longitudinal extension takes place once, but can also take place more than once, i.e. multiple times.

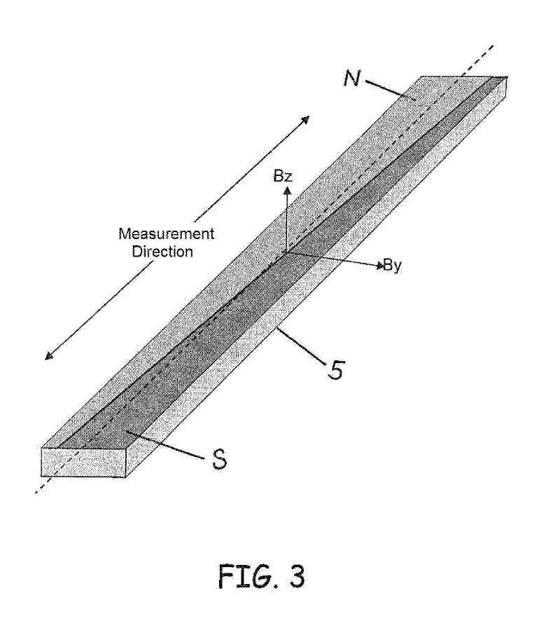

FIG. 3 shows, based on the diagonally magnetized magnet 5, the principle of operation of the sensor assembly according to the invention, the following explanations applying also to the helically magnetized magnet 5. Since the magnet 5 is carried on the relatively linearly movable element 3, the angles of the magnetic field lines are continuously changed relative to the sensor 4 during movement of the magnet 5 relative to the stationary support 2 due to the position change of the structure whose position is to be detected, the change being detected and evaluated. In the illustrated example according to FIG. 2, the magnetic portions By and Bz of the field lines detected perpendicular to the movement direction (measuring direction) are used as absolute values for the calculation of the actual position of the magnet. In simple terms, this means that from the arctangent function of the ratio By to Bz [arctan (By/Bz)], the position of the magnet 5 (and thus of the structure whose position is to be detected) relative to the stationary sensor 4 can be concluded.

1. A sensor assembly for detecting a position of a linearly movable element and having a magnet and a sensor detecting the position of the magnet, wherein a stationary support is provided that carries the sensor and that guides the element having the magnet and linearly movable relative to the support.

2. The sensor assembly according to claim 1, wherein the sensor is configured as a magnetically sensitive sensor.

3. The sensor assembly according to claim 1, wherein the magnet is elongated, has an angular cross-section, and is diagonally magnetized along its longitudinal extension.

4. The sensor assembly according to claim 3, wherein the magnet is a plastic-bonded magnet.

5. The sensor assembly according to claim 4, wherein the magnet is formed from an anisotropic magnet material.

6. The sensor assembly according to claim 1, wherein the magnet is elongated and has a round or oval cross-section and is helically magnetized along its longitudinal extension.

7. The sensor assembly according to claim 6, wherein the magnet is extruded as a plastic-bonded magnet.

8. The sensor assembly according to claim 7, wherein the magnet is formed from an anisotropic magnet material.

9. The sensor assembly according to claim 1, wherein the support or the linearly movable element is a plastic injection-molded part.
